(19) United States
(12) Patent Application Publication
(10) Pub. No.: US 2013/0299993 A1
(43) Pub. Date: Nov. 14, 2013

(54) INTERCONNECTION OF SEMICONDUCTOR DEVICE AND FABRICATION METHOD THEREOF

(71) Applicant: Hsin-Yu Chen, Nantou County (TW)

(72) Inventor: Hsin-Yu Chen, Nantou County (TW)

(21) Appl. No.: 13/469,093

(22) Filed: May 11, 2012

(51) Int. Cl. H01L 23/48; H01L 21/768

(52) U.S. Cl. 257/770; 438/675; 257/741; 257/E21.586; 257/E23.01

(57) ABSTRACT

The present invention provides a method for fabricating an interconnection of a semiconductor device, which includes the following processes. First, an isolation layer is formed on a substrate. Then, at least a first trenches extending along a first direction is formed in the isolation layer. The first trench is then filled up with a first conductive material followed by forming a patterned mask layer on the substrate, wherein the patterned mask exposes parts of the isolation layer and part of the first conductive material. Finally, at least a second trench extending along a second direction is formed in the isolation layer, wherein the at least one second trenches intersects and overlaps portions of the at least one first trenches.

### BACKGROUND OF THE INVENTION

1. Field of the Invention

The present invention generally relates to the field of interconnection structures for semiconductor devices, and more particularly to an interconnection structure and a fabricating method thereof.

2. Description of the Prior Art

Along with the continuous miniaturization of the Integrated Circuits (IC), the line width of interconnections and the feature size of semiconductor devices have continuously shrunk. In general, discrete devices in integrated circuits are connected to each other through contact plugs (or contact slots) and interconnection structures, so that the related fabrication method are became an important matter in the next-generation semiconductor devices.

In current fabricating processes, due to the limitations of the back end of the line (BEOL) process capacity, the yield of contact plugs with high aspect ratio (HAR) is relatively low and cannot reach the requirements. In order to overcome this drawback, a double patterning technique, generally including two photolithographic and two etching processes (2P2E), is invented in order to fabricate required device pattern. However, in a case for forming trenches extending along different direction, intersections between the trenches are often over etched during an etching step. In addition, the profile and the etching degree at these intersections usually vary from locations to locations (from wafer center to wafer edge for example). It becomes apparent that all of these phenomena are bad for the reliability of the fabricating process.

Accordingly, in order to overcome the above-mentioned drawbacks, there is a need to provide a modified method for fabricating an interconnection structure with a better yield.

### SUMMARY OF THE INVENTION

One objective of the invention is therefore to provide a method for fabricating an interconnection which can overcome the drawbacks described above.

To address these and other objectives, according to one embodiment of the invention, a method for fabricating an interconnection in a semiconductor device is provided, which includes the following processes. First, an isolation layer is formed on a substrate. Then, at least a first trench extending along a first direction is formed in the isolation layer. The first trench is then filled up with a first conductive material followed by forming a patterned mask layer on the substrate, wherein the patterned mask exposes part of the isolation layer and part of the first conductive material. Finally, at least a second trench extending along a second direction is formed in the isolation layer, wherein the at least one second trench intersects and overlaps portion of the at least one first trench.

In another embodiment of the present invention, a method for fabricating an interconnection in a semiconductor device is provided. An isolation layer is formed on a substrate; a first mask process is carried out to form at least a first trench extending along a first direction in the isolation layer; the first trench is filled up with a first conductive material; a second mask process is performed to form at least a second trenches extending along a second direction in the isolation, wherein the at least one second trench intersects and overlaps a portion of the at least one first trench; and the second trench is filled up with a second conductive material.

According to still another embodiment of the present invention, a method for fabricating an interconnection of semiconductor devices is provided. A substrate having an isolation layer thereon is provided; at least a first conductive line extending along a first direction is formed in the isolation layer; at least a second conductive line extending along a second direction is formed in the isolation layer, wherein the second conductive line intersects the first conductive line; and a first conductive layer disposed between the first conductive line and the second conductive line, wherein the first conductive layer is located on each sidewall of the first conductive line and directly contacts the first conductive line.

One feature of the present invention resides in the fact that the first conductive lines extending along a first direction are formed first, so that they can act as an etching mask during the formation of the second trenches. In other words, during the formation of the second trenches, the first trenches are already filled up with the first conductive material. As a consequence, the target layer located at the intersection of the first trenches and the second trenches will no longer be over etched and the yield of the interconnection structure can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIGS. 1-8 depict a series of schematic diagrams of a method for fabricating an interconnection structure of a semiconductor device in accordance with embodiments of the invention, wherein:

FIGS. 1 and 2 respectively show a schematic, top view and a cross-sectional diagram illustrating a substrate having a target layer, an isolation layer and a first patterned mask layer thereon;

FIGS. 3 and 4 respectively show a schematic, top view and a cross-sectional diagram illustrating a substrate having a plurality of first trenches thereon;

FIG. 5 is a schematic, cross-sectional diagram showing first trenches filled up with first conductive material; and

FIGS. 6 to 8 are schematic diagrams showing a method for fabricating second conductive lines.

FIG. 9 is a schematic, cross-sectional diagram showing the intersection of first conductive lines and second conductive lines in an interconnection structure according to one embodiment of the invention; and

FIG. 10 is a schematic, cross-sectional diagram showing the intersection of first conductive lines and second conductive lines after accomplishing a dual damascene process according to one embodiment of the invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

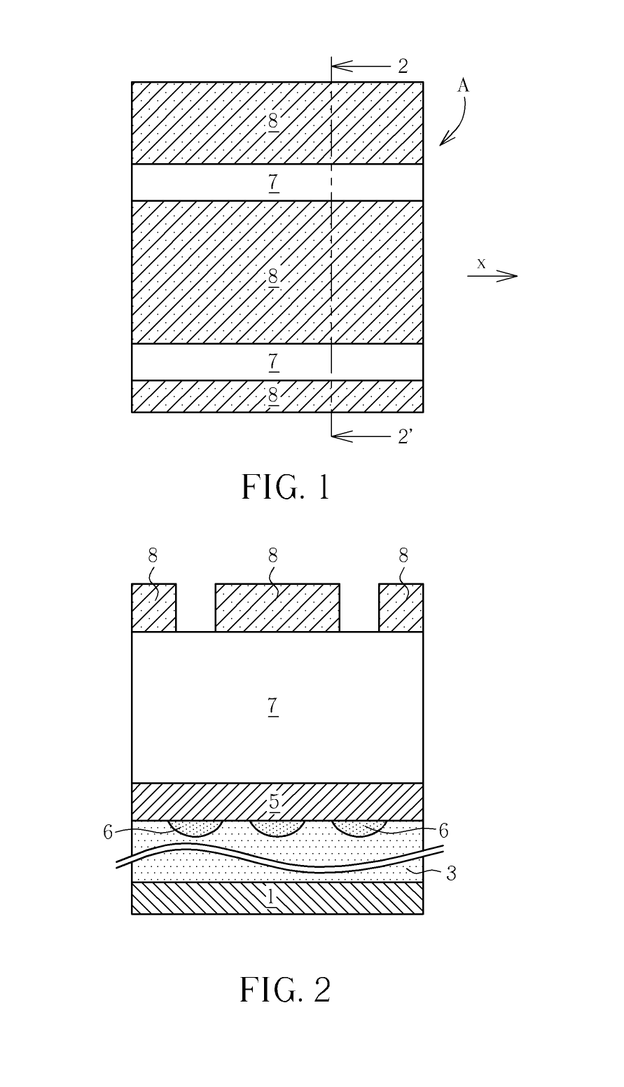

Please refer to FIGS. 1 to 8, which depict a series of schematic diagrams of a method for fabricating an interconnection structure for a semiconductor device in accordance with embodiments of the invention. FIG. 1 is a schematic top view illustrating a substrate 1 having a target layer 3, an isolation layer 7 and a first patterned mask layer 8 thereon. FIG. 2 is a schematic, cross-sectional diagram taken a long a line 2-2′ in FIG. 1. In FIGS. 1 and 2, the substrate 1 may include a semiconductor substrate, such as silicon substrate, silicon germanium (SiGe) substrate, silicon-on-insulator (SOI) substrate or the likes; the target layer 3 may be a dielectric layer, such as an inter layer dielectric (ILD) or an inter metal dielectric (IMD), having several electronic components therein. The electronic components may include source/drain regions, gate structures, doped regions, contact plugs, conductive lines and so forth. Therefore, the composition of these electronic components includes single crystal silicon, polycrystalline silicon, amorphous silicon, metal silicide, metal or the likes; the isolation layer 7, also preferably comprises dielectric material such as silicon oxide, low-k dielectric material or the likes, and processes for making those may include a thermal oxidation process, a high density plasma CVD (HPCVD) process or a sub atmosphere CVD (SACVD) process, but is not limited thereto. In this embodiment, a cap layer 5 is located between the target layer 3 and the isolation layer 7, which can serve as an etch stop layer in order to protect the electronic components 6 from being damaged during the fabrication processes.

The first patterned mask layer 8, such as a patterned photoresist layer, has a first mask pattern A which can expose a portion of the isolation layer 7 and let the exposed isolation layer 7 extend along a first direction x. Therefore, in this embodiment, the first patterned mask layer 8 can act as an etch mask to define first trenches (not shown) in subsequent processes.

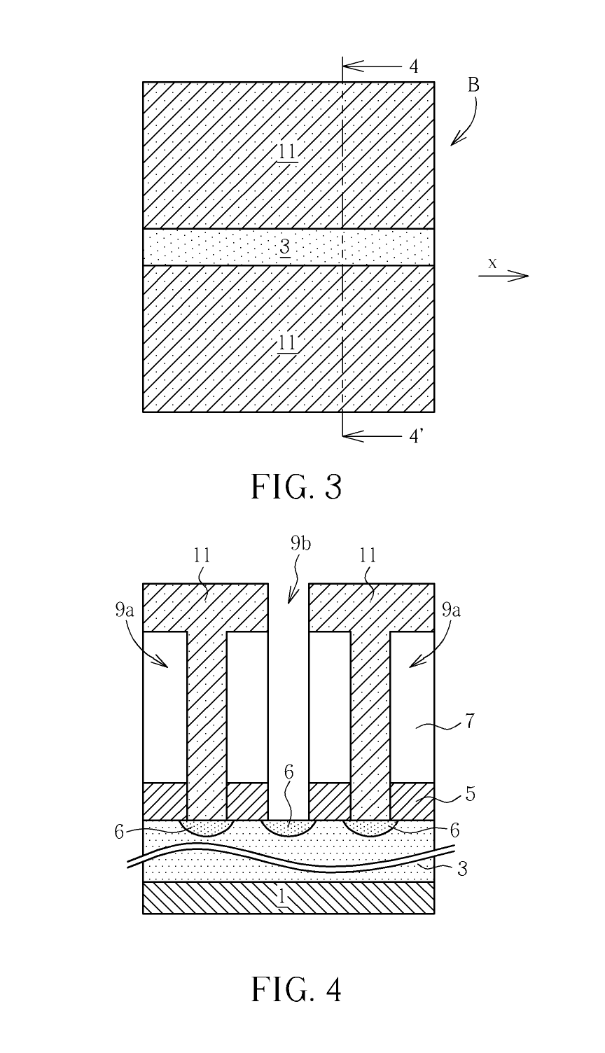

Please refer to FIGS. 3 and 4, where FIG. 3 is a schematic top view illustrating a structure subsequent to the above procedure while FIG. 4 is a schematic cross-sectional diagram taken a long a line 4-4′ in FIG. 3. As shown in FIGS. 3 and 4, after the first patterned mask layer 8 is formed on the substrate 1, at least an etching process is carried out to define a plurality of first trenches 9a.

A second patterned mask layer 11 can act as an etch mask to define other first trenches 9b. For example, a photoresist is deposited onto the substrate 1 and fills up each first trench 9a. A series of processes, like exposing, developing, baking and other processes are then carried out so as to form a second patterned mask layer 11. The second patterned mask layer 11 has a pattern corresponding to a first mask pattern B and expose portions of the isolation layer 7 and let the exposed isolation layer 7 extend along a first direction x. The second patterned mask layer 11 is then used as an etch mask to define a plurality of first trenches 9b in the isolation layer 7 through at least an etching process. As a result, a plurality of first trenches 9 (including the first trenches 9a and 9b) extending along a first direction x may be defined by the first patterned mask layer 8 and the second patterned mask layer 11. In other words, in the above-mentioned embodiment, a first mask process, including the first mask pattern A and the first mask pattern B, is carried out to define the first trenches 9 and may be deemed as an application of double patterning technique (also called 2P2E). In addition, an unique developing and etching process, 2P1E or other appropriate procedures may be utilized in the present invention to form the first trenches 9 (including the first trenches 9a and 9b) extending along a first direction x

In addition, in the above embodiment, during the formation of the first trenches 9a and 9b, etching procedures with one etching recipe are performed first to etch the isolation layer 7 down to the surface of the cap layer 5, then other etching procedures with different etching recipes or wet etching processes are carried out to etch through the cap layer 5 until the underlying electronic components 6 are exposed. However, without departing from the scope and the spirit of the invention, the present invention is not limited to these procedures.

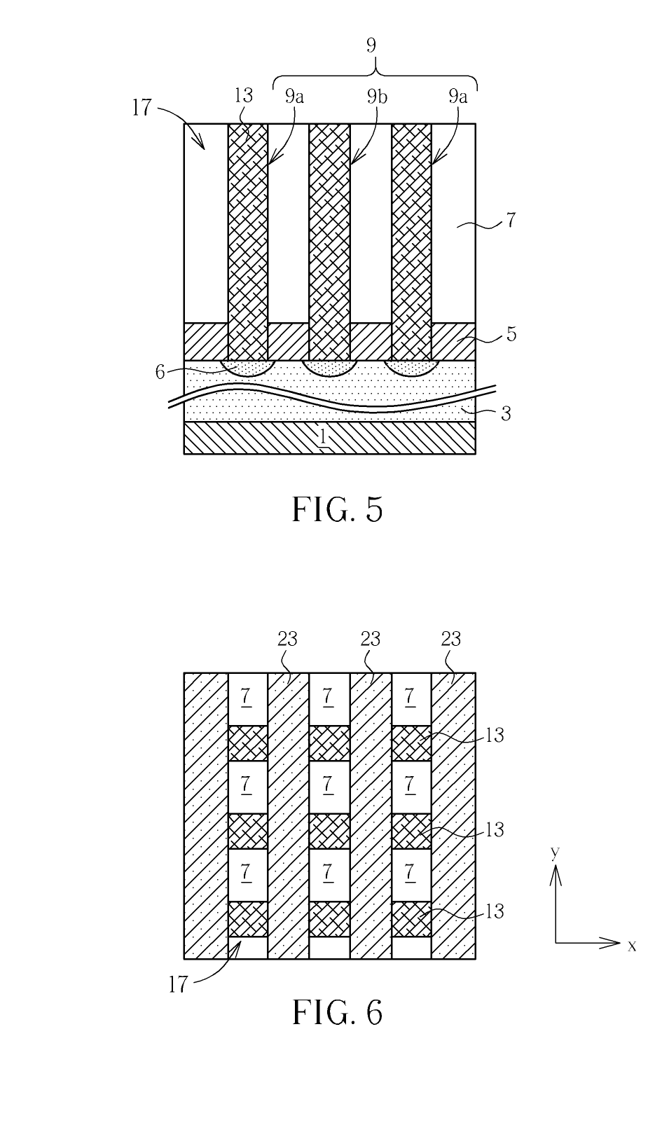

After the second patterned mask layer 11 are removed, a plurality of first trenches 9 (including the first trenches 9a and 9b) extending along a first direction x are now exposed and are located in the isolation layer 7 and the cap layer 5. Additionally, each first trench 9 can expose portions of the target layer 3 and the corresponding electronic components 6. FIG. 5 is a schematic cross-sectional diagram showing the first trenches 9 filled up with a first conductive material 13. The structure shown in FIG. 5 may be obtained by sequentially performing a deposition process and a polishing process, such as chemical mechanical process (CMP), so that the first conductive material 13 can fill up the first trenches 9 and electrically connect the corresponding electronic components 6 in the target layer 3. The first conductive material 13 may comprise tungsten, copper, aluminum or gold. In addition, a conductive layer (not shown) may be formed on the surface of the first trenches 9 before filling the first conductive material 13. In this way, the growth rate or the adhesive property of the first conductive material 13 can be improved. For example, when the first conductive material 13 is selected from tungsten, the conductive layer may be chosen from titanium, tantanum, titanium nitride or titanium nitride as a kind of barrier layer; while if the first conductive material 13 is selected from copper, the conductive layer may be further comprise copper seeds (not shown) to enhance the growth of the copper. This time, first conductive lines 17 extending along the first direction x are formed on the substrate 1 and the top surface of each first conductive lines 17 is substantially leveled with the top surface of the isolation layer 7. According to another embodiment of the invention, a cap layer, such as silicon nitride, silicon oxide or other isolation material, may optionally be formed to cover the surface of the first conductive lines 17 and the isolation layer 7. In this way, the surface of the first conductive lines 17 will not be over etched or diffuse out in the subsequent procedures.

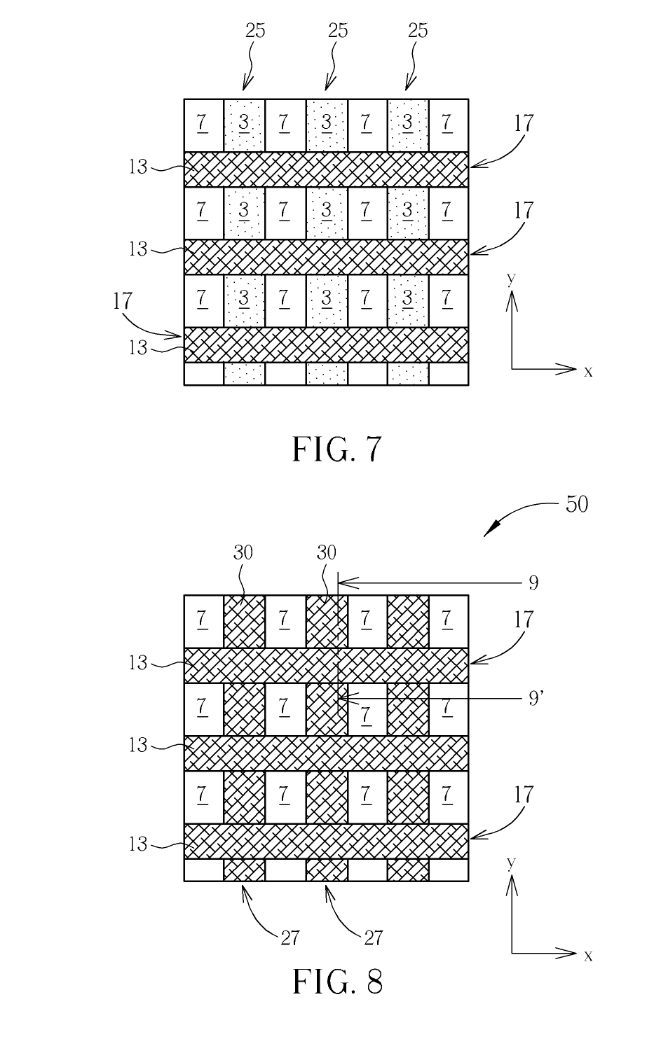

In the above paragraphs, the fabrication processes for the first conductive lines 17 are described in detail. Now please refer to FIGS. 6 to 8, which are schematic diagrams showing a method for fabricating second conductive lines. First, as shown in FIGS. 6 and 7, a second mask process is carried out in order to form a plurality of second trenches 25 extending along a second direction y in the isolation 7. The detailed procedures are described as follows. First, a third patterned mask 23, such as a patterned photoresist, is formed to expose portions of each first conductive line 17 and portions of the isolation layer 7. Then, by using the third patterned mask 23 and the first conductive lines 17 as etch masks, etching procedures with at least one etching recipe are performed to etch the isolation layer 7 and the cap layer 5 down to the surface of the target layer 3. At this time, a plurality of second trenches 25 extending along a second direction y is formed in the isolation layer 7, wherein the first direction x is not parallel to the second direction y. In this case, each of the second trenches 25 intersects and overlaps each of the first trenches 9 (the first trenches 9 are now filled up with first conductive material 13). Accordingly, one feature of the present invention resides in the fact that the first trenches 9 are formed earlier than the second trenches 25. That is to say that, after the first trenches 9 are filled up with the first conductive material 13, the second trenches 25 start to be formed. In this situation, the target layer 3 at the intersection between the first trenches 9 and the second trenches 25 will no longer be over etched. It should be noted that, the above method for forming the second trenches 25 utilizes a unique developing and etching process, it is however preferably replaced by an application of double patterning technique (also called 2P2E). Since the fabrication of the second trenches 25 is similar to that of the first trenches 9, the description of which is therefore omitted for the sake of clarity.

After the second trenches 25 are formed, please refer to FIG. 8., which is a schematic diagram showing second trenches 25 filled up with second conductive material 30. The structure shown in FIG. 8 may for example be accomplished by sequentially performing a deposition and a polishing process, such as chemical mechanical process (CMP), so that the second conductive material 30 can fill up each second trench 25 to form a plurality of second conductive lines 27. The composition and the formation steps of the second conductive lines 27 are similar to that of the first conductive line 17. For example, the second conductive material 30 may comprise tungsten, copper, aluminum or gold. In addition, before filling the second conductive material 30 into the second trenches 25, a conductive layer (not shown) may be formed. In this way, the growth rate or the adhesive property of the second conductive material 30 can be improved. For example, when the second conductive material 30 is selected to be tungsten, the conductive layer may be chosen from titanium, tantanum, titanium nitride or titanium nitride as a kind of barrier layer; while if the second conductive material 30 is selected to be copper, the conductive layer may further comprise copper seeds (not shown) to enhance the growth of the copper. At this time, a plurality of conductive lines 17 and 27 respectively extending along a first direction x and a second direction y are formed on the substrate 1. And the top surface of the first conductive line 17 and the top surface of the second conductive lines 27 are substantially leveled with that of the isolation layer 7 and all of them are coplanar. Therefore, an interconnection structure 50 of a semiconductor device according to one embodiment of the present invention is accomplished.

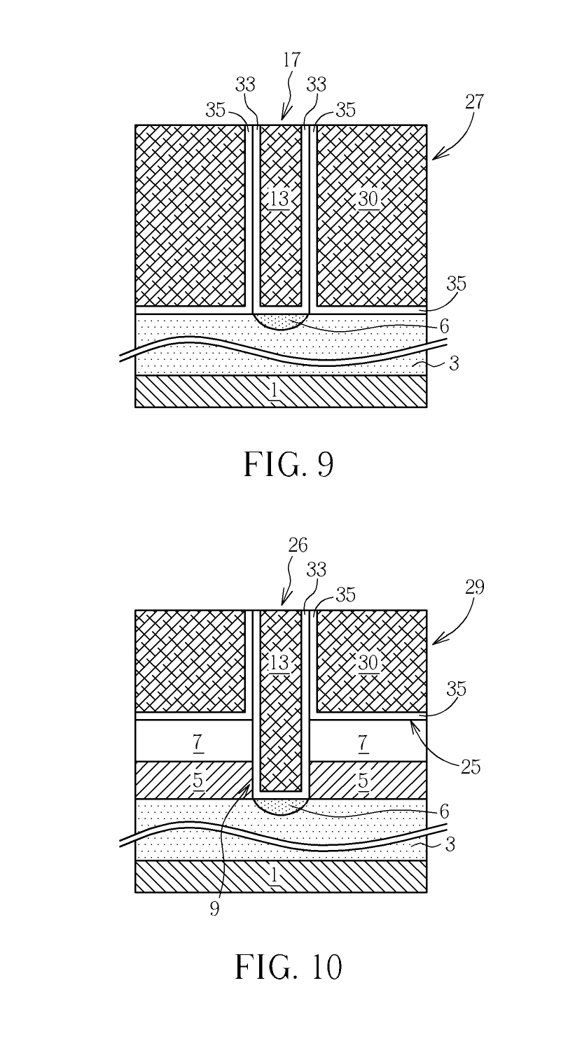

It should be noted that, the first trenches 9 are formed and filled up with the first conductive material 13 before the second trenches 25 are formed and filled up with the second conductive material 25. In addition, the conductive layers 33 and 35, as a kind of barrier layer, adhesive layer or seed layer, may be formed in the respective first trenches 9 and second trenches 25 before the deposition of the first conductive material 13 and the second conductive material 25. As a result, first trenches 9 extending along a first direction x intersect and overlap the second trenches 25 extending along a second direction y. Additionally, all the first conductive lines 17 and second conductive lines 27 are in xy plane and are connected to each other through the conductive layer 33 and 35 in between. FIG. 9, which is a schematic, cross-sectional diagram taken along a line 9-9′ in the FIG. 8. In FIG. 9, the bottom and the sidewalls of the first conductive lines 17 are covered with the conductive layer 33; similarly, the bottom and the sidewalls of the second conductive lines 27 are covered with the conductive layer 35. Accordingly, an electrical signal can be transmitted between the first conductive lines 17 and the second conductive lines 27 through both conductive layers 33 and 35. According to one embodiment of the present invention, if the first conductive lines 17 and the second conductive lines 27 are fabricated through tungsten deposition and polishing processes, the first conductive material 13 and the second conductive material 30 will comprise tungsten and the conductive layers 33 and 35 are preferably barrier layers comprising Ti/TiN or Ta/TaN, but are not limited to. In addition, a composition of the first conductive material 13 may be different from that of the second conductive material 30. For instance, if the first conductive material 13 comprises tungsten, the second conductive material 30 may comprise Al, Au, copper or other suitable metal, and vice versa. Furthermore, the composition of the conductive layer 33 may be different from that of the conductive layer 35.

Please refer to FIG. 10, which is a schematic, cross-sectional diagram taken along a line 9-9′ in FIG. 8. The main difference between the structure shown in FIG. 10 and that shown in FIG. 9 is that at least one of the first conductive line 17 and the second conductive line 27 is obtained through a dual damascene process. They are preferably both integrated through dual damascene processes. Accordingly, the only main difference is described in the following paragraphs. First, a first mask process is carried out to form a plurality of first trenches 9 extending along a first direction x in the isolation layer 7 and the cap layer 5. The first trenches 9 may expose the corresponding electronic components 6 in the target layer 3. Subsequently, a conductive layer 33 and a first conductive material 13 are filled into the first trenches 9 to form contact plugs 26. A second mask process is then performed so that a plurality of second trenches 25 extending along a second direction y is formed in the isolation layer 7. Finally, a conductive layer 35 and a second conductive material 35 are filled into the second trenches 25 to form conductive lines 29. Accordingly, each of the second trenches 25 along a second direction y intersects and overlaps portions of each of the first trenches 9 along a first direction x so that the contact plugs 26 and the conductive lines 29 are in a XY plane (parallel to the surface of the substrate 1) and electrically connected to each other through the conductive layer 33 and 35. If the processes are integrated with dual damascene processes, the first conductive lines 17 and the second conductive lines 27 are preferably copper and the conductive layers 33 and 35 preferably include copper seed layer and barrier layers comprising Ti/TiN or Ta/TaN, but is not limited thereto. In addition, a composition of the first conductive material 13 may be different from that of the second conductive material 30. Also, the composition of the conductive layer 33 may be different from that of the conductive layer 35.

It is worth noting that each of the first conductive lines 17 and the second conductive lines 27 can not only act as a contact plug or a contact slot used to directly contact and electrically connect the electronic components 6 (such as source/drain or gate structure) in the target layer 3 but also act as a metal 0 (M0) to directly contact the contact plugs 6 and further electrically connect other regions under or in the target layer 3 through the contact plugs 6. Furthermore, the interconnection structure 50 may be deemed as one of the interconnection level (also called metal one (M1), metal 2 (M2) and so forth), which may be connected to other interconnection levels through via plugs 6. Therefore, the interconnection structure 50 shown in the present invention may be applied to connect devices like NMOS, PMOS, semiconductor resistors, diode devices, photosensitive devices, bipolar junction transistors (BJT) or the likes.

To summarize, the present invention provides an interconnection structure and a fabrication method thereof. One feature of the present invention is the presence of the first conductive lines extending along a first direction x that are formed in a first step, which can act as an etching mask during the formation of the second trenches. Finally, the second conductive material fills up the second trenches so that several second conductive lines extending along the second direction y are formed. In other words, during the formation of the second trenches, the first trenches are already filled up with the first conductive material. As a consequence, the target layer located at the intersection of the first trenches and the second trenches will no longer be over etched and the yield of the interconnection structure can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fabrication method for an interconnection of semiconductor devices, comprising:
forming an isolation layer on a substrate;
forming at least a first trench extending along a first direction in the isolation layer;
filling up the first trench with a first conductive material;
forming a patterned mask layer on the substrate, wherein the patterned mask exposes a part of the isolation layer and a part of the first conductive material; and
forming at least a second trench extending along a second direction in the isolation layer, wherein the at least one second trench intersects and overlaps portions of the at least one first trench.

2. The method according to claim 1, which further comprises a step of filling up the second trench with a second conductive material after forming the second trench.

3. The method according to claim 2, wherein the second conductive material in the second trench and the first conductive material in the first trench comprise a dual damascene structure.

4. The method according to claim 2, wherein a composition of the second conductive material is different from a composition of the first conductive material.

5. The method according to claim 2, wherein the first conductive material and the second conductive material comprise tungsten, copper, aluminum or gold.

6. The method according to claim 1, which further comprises a step of filling up the first trench with a conductive layer before filling up the first trench with the first conductive material.

7. The method according to claim 1, which further comprises a step of filling up the second trench with a conductive layer before filling up the second trench with the second conductive material.

8. A fabrication method for an interconnection of semiconductor devices, comprising:
forming an isolation layer on a substrate;
performing a first mask process to form at least a first trench extending along a first direction in the isolation layer;
filling up the first trench with a first conductive material;
performing a second mask process to form at least a second trench extending along a second direction in the isolation, wherein the at least one second trench intersects and overlaps portion of the at least one first trench; and
filling up the second trench with a second conductive material.

9. The method according to claim 8, wherein at least one of the first mask process and the second mask process is a double-patterning process.

10. The method according to claim 8, wherein a composition of the second conductive material is different from a composition of the first conductive material.

11. The method according to claim 8, which further comprises a step of filling up the first trench with a conductive layer before filling up the first trench with the first conductive material.

12. The method according to claim 8, which further comprises a step of filling up the second trenches with a conductive layer before filling up the second trenches with the second conductive material.

13. The method according to claim 8, wherein the second conductive material in the second trench and the first conductive material in the first trench comprises a dual damascene structure.

14. The method according to claim 8, wherein the first conductive material and the second conductive material comprise tungsten, copper, aluminum or gold.

15. The method according to claim 8, wherein the first direction is not parallel to the second direction.

16. An interconnection of semiconductor devices, comprising:
a substrate having an isolation layer thereon;
at least a first conductive line extending along a first direction in the isolation layer;
at least a second conductive line extending along a second direction in the isolation layer, wherein the second conductive line intersects the first conductive line; and
a first conductive layer disposed between the first conductive line and the second conductive line, wherein the first conductive layer is located on each sidewall of the first conductive line and directly contacts the first conductive line.

17. The structure according to claim 16, further comprising a second conductive layer disposed between the first conductive line and the second conductive line, wherein the second conductive layer is located on each sidewall of the second conductive line and directly contacts the first conductive layer.

18. The structure according to claim 16, wherein a top surface of the first conductive line or a top surface of the second conductive line is substantially leveled with a top surface of the isolation layer and is coplanar.

19. The structure according to claim 16, wherein a composition of the first conductive material is different from a composition of the second conductive material.

20. The structure according to claim 16, wherein the conductive layer is selected from the group consisting of copper seed, titanium, tantanum, titanium nitride and titanium nitride.
